(19) United States
(12) Patent Application Publication
(10) Pub. No.: US 2007/0194436 A1
(43) Pub. Date: Aug. 23, 2007

(54) Ball grid array package

(75) Inventors: Chung-Yao Kao, Ping Tung Hsien (TW); Chun-Yang Lee, Kaohsiung City (TW); Meng-Jen Wang, Ping Tung City (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/652,059

(22) Filed: Jan. 11, 2007

(30) Foreign Application Priority Data
Feb. 17, 2006 (TW) 95105436

(51) Int. Cl. H01L 23/12

(52) U.S. Cl. 257/700

(57) ABSTRACT

A ball grid array package includes a substrate having a lower surface formed with several ball-mounting regions, a selective pad-mounting block, and an identifying mark for indicating the selective pad-mounting block. A die is disposed on an upper surface of the substrate. A molding resin is encapsulated on the substrate for enclosing the die. A plurality of solder balls is mounted on the lower surface of the substrate and is coupled electrically to the die for establishing electrical communication with an external electronic device.

### FIELD OF THE INVENTION

The invention relates to a circuit board, and more particularly to a circuit board provided with identifying marks.

### BACKGROUND OF THE INVENTION

Due to rapid development in the integrated circuit technology, a chipset is provided with several densely located integrated circuit according to the increased functions. The same is occurred in the input/output (I/O) pins for the chipset. The traditional DIP (dual in-line package) or QFP (quad flat package) cannot fulfill the requirements of the today chipset so that the major package method is in the form of ball grid array package.

A ball grid array package generally includes a substrate having a lower surface formed with an array of ball-mounting pads for the solder balls to be mounted. After assembly, the solder balls of the ball grid array package are coupled respectively to the contact points of a circuit board.

Several methods are used for mounting solder balls on the pads. For example, in the screen-printing technique, a predetermined amount of solder paste is screen printed onto the solder pads for forming the solder balls thereon. The substrate is then undergone a reflow process, in which, the solder paste is heated and thereafter the solder balls are formed due to the surface shrinkage.

Alternately, a ball-mounting method is used. Firstly, a flux is coated on the solder pads. Then, the preformed solder balls are disposed on the solder pads by using special tools such that the solder balls are stuck temporarily on the solder pads by virtue of the flux. Finally, the whole assembly is passed through the reflow process so as to fix the solder balls on the solder pads.

Note that the manufacturers may provide several models with the die having slightly different function abilities from one another based on the production cost to fulfill the variety of requirements of the markets.

The die of a specific model may have function ability different from another model number. But, the similar die is used for basic functions. Therefore, during the packing operation, each of the dies is disposed on the same substrate. However, the dies of different models may have different I/O pins according to the function ability. Therefore, the solder balls on the solder pads of the substrate for establishing electrical communication with an external electronic device may also differ in numbers.

For example, same type but different models of two dies may be mounted on the same type substrate. Therefore, the number and position of each corresponding solder ball on the substrate of such two chipsets may be the same. However, a predetermined amount of the solder pads is not required to be provided with solder balls for one specific model, but not true for another.

On the other hand, the solder balls may suffer disengagement from the solder pads due to collision or planting error or some unavoidable circumstances during the printing process regardless of whatever ball-mounting method is applied.

Thus, during the production of the package, the assembler usually checks the package in accordance with the production list to assure or determine whether the desired positions are in fact provided with the solder balls or without. This type of checking operation results in low efficiency and waste of time. The items are randomly examined, thereby causing a serious burden for electrical performance testing in the final testing process.

Moreover, a tester may make error judgment easily when checking the positions of the solder balls based on the production list. For instance, in case he finds out a solder ball dropped from a specific ball-mounting pad, the specific ball-mounting pad being located closely to an area, where the solder ball is not required according to the production list. He may wrongly determine that the solder ball doesn't need to be mounted on the specific ball-mounting pad, which, in turn, is contrary to the fact. Since there can be several hundreds of I/O balls in one package, the possibility of making error during the testing operation is accordingly increased.

### SUMMARY OF THE INVENTION

The object of the present invention is to provide a substrate for use in a ball grid array package. The substrate has a plurality of ball-mounting pads and an identifying mark disposed adjacent to a specific portion of the ball-mounting pads so as to assure that the specific ball-mounting pads are required to be provided with solder balls or not.

In one aspect of the present invention, a circuit board is provided to include a substrate having an upper surface, a lower surface formed with a plurality of bond pads including several ball-mounting pads and several selective ball-mounting pad; and a plurality of identifying marks disposed on the lower surface for indicating the selective ball-mounting pad respectively.

In anther aspect of the present invention, a ball grid array package is provided to include a substrate having a lower surface formed with several ball-mounting regions, a selective pad-mounting block, and an identifying mark for indicating the selective pad-mounting block; a die disposed on an upper surface of the substrate; a molding compound for encapsulating the die on the substrate; and a plurality of solder balls mounted on the lower surface of the substrate and coupled electrically to the die for establishing electrical communication with an external electronic device.

### BRIEF DESCRIPTION OF THE DRAWING

Other features and advantages of this invention will become more apparent in the following detailed description of the preferred embodiments of this invention, with reference to the accompanying drawings, in which:

FIG. 1 shows a sectional view of one embodiment of a ball grid array package of the present invention;

FIG. 2A is a bottom side view of a substrate employed in the ball grid array package of the present invention;

FIG. 2B is an enlarged view of an encircled portion shown in FIG. 2A;

FIG. 3A is a bottom side view of another substrate employed in the ball grid array package of the present invention; and

FIG. 3B is an enlarged view of an encircled portion shown in FIG. 3A.

### DETAILED DESCRIPTIONS OF THE PREFERRED EMBODIMENTS

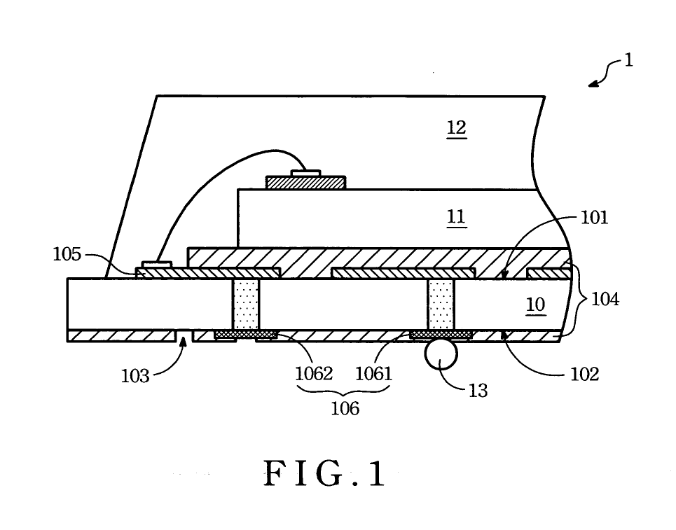

FIG. 1 shows a cross-sectional view of a first embodiment of a ball grid array packet 1 of the present invention and includes circuit substrate 10, a die 11, a 12 and a plurality of solder balls 13.

The circuit substrate 10 is formed for carrying different dies thereon. The circuit substrate 10 has an upper surface 101, a lower surface 102 opposite to the upper surface 101 and formed with at least one identifying mark 103.

Two metal layers (such as copper alloy layers) are disposed on the upper and lower surfaces 101, 102 of the substrate 10 and are patterned to form upper and lower circuit patterns having metal pads. Each solder mask is coated onto a respective metal pad and serves as the solder resistant layer 104. The solder resistant layer 104 is formed with a plurality of openings (only one is shown in the drawing) at predetermined positions in order to expose predetermined sections of the conductive traces. The exposed conductive traces on the upper circuit pattern is called bonding finger pad 105 while the exposed conductive traces on the lower circuit pattern is called sold pad 106. The circuit substrate 10 is further formed with a plurality of through holes for connecting the boding finger pad 105 and the ball-mounting pad 106.

The ball-mounting pad 106 is further classified as a ball-mounting pad section 1061 and a selective ball-mounting pad section 1062 based on the solder ball design and according to the model number of the die.

A silver paste is coated on the upper surface of the circuit substrate 10 to stick the die 11 that has input/output (I/O) contacts at an outer surface for connecting electrically to the bonding finger pad 105 and the ball-mounting pad 106 via the internal wire bonding method.

The molding resin 12 is encapsulated on the upper surface of the circuit substrate 10 so as to enclose the die 11 hermetically. Under this condition, the external humidity is prevented from causing influence on the die 11.

A plurality of solder balls 13 are fixed on the ball-mounting pad section 1061 and the selective ball-mounting pad section 1062 according to the model numbers of the dies 12. The solder balls 13 are further connected electrically to the die 11 for serving as the external terminals of the ball grid array package 1. A solder paste or ball mounting technique can also be used for fixing the solder balls 13 on the ball-mounting pad 106.

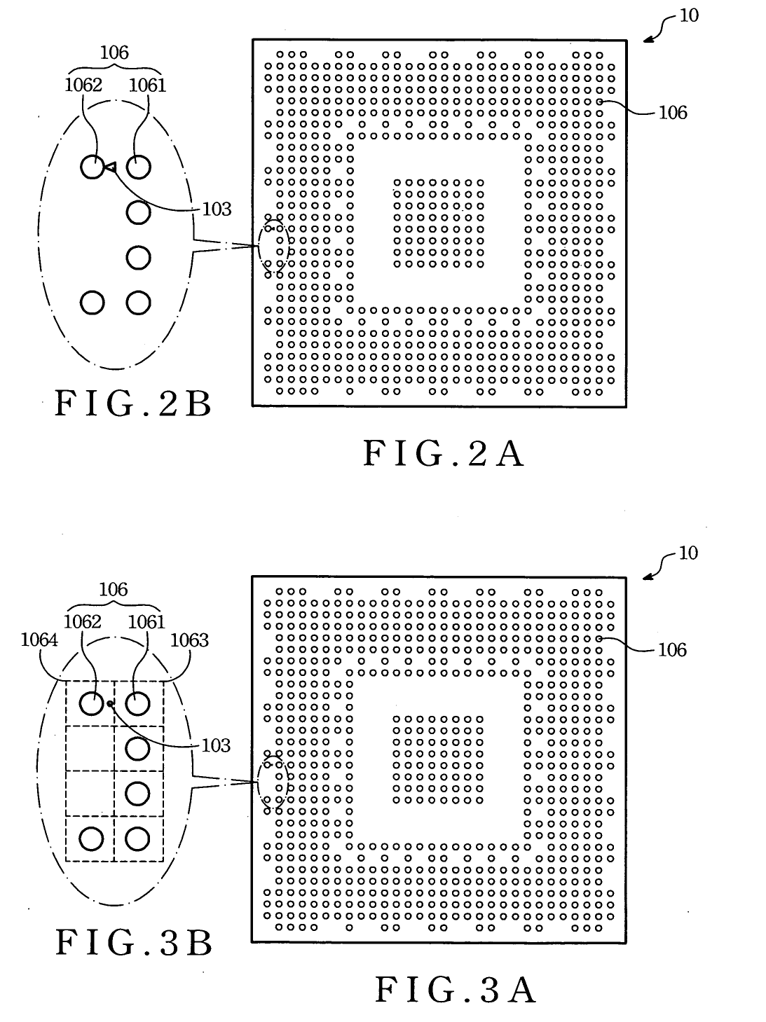

FIGS. 2A and 2B show bottom side views of the circuit substrate 10 of the present invention for illustrating the identifying marks 103 and ball-mounting pads on the bottom surface, wherein the solder balls are not shown.

As mentioned above, the ball-mounting pad 106 is classified into the ball-mounting pad sections 1061 and the selective ball-mounting pad sections 1062. The identifying marks 103 are formed on the lower surface of the circuit substrate 10 for indicating the selective ball-mounting pad sections 1062 respectively. The identifying marks 103 may be presented by any directional indentations, such as an acute triangle with a vertex pointing toward a respective ball-mounting pad in the selective ball-mounting pad section 1062.

FIGS. 3A and 3B show bottom side views of the circuit substrate 10 in another embodiment of the ball grid array package of the present invention, illustrating the identifying marks 103 and ball-mounting pads on the bottom surface, wherein the solder balls are not shown. The identifying mark 103 is disposed adjacent to for indicating the selective ball-mounting pad section 1062. The identifying mark 103 is rounded, and has no vertex for indicating the respective selective ball-mounting pad section 1062.

As illustrated, the bottom surface of the circuit substrate 10 is divided into several first and second regions 1063, 1064 for confining the ball-mounting pad sections 1061 and the selective ball-mounting pad sections 1062.

Each of the ball-mounting pad sections 1061 confined by the respective first region 1063 is implanted with a solder ball. The selective ball-mounting pad section 1062 confined by the respective second region 1064 is to be provided with a solder ball or not depends the model number of the die that is to be disposed on the substrate 10 via flip-chip technique.

Since the identifying mark 103 is disposed within the respective second region 1064, the selective ball-mounting pad section 1062 can be easily located.

In other word, there is a central line separating the ball-mounting pad sections 1061 and the selective ball-mounting pad sections 1062. When an identifying mark is present between the ball-mounting pads 106, by judging the close location of the identifying mark 103 with respect to the respective ball-mounting pad 106, one can determine the previously mentioned selective ball-mounting pad section 1062 is located within the second region 1604 such that the respective selective ball-mounting pad section 1062 is not required to be provided with the solder ball 13.

In one embodiment, an opening formed through the solder resistant layer 104 may serve as the identifying mark 103. The identifying mark 103 within the second region 1064 may have other configuration, similar to the triangle of the previous embodiment, indicating the optional pad section 1062.

By verifying the identifying mark on the substrate, the user or assembler of the ball grid array package of the present invention can easily determine, which ball-mounting pad is the selected ball-mounting pad. During the testing operation, the assembler can check out the absence or presence of the solder ball at the respective ball-mounting pad.

Upon checking out a missing solder ball from the substrate, the assembler or tester only needs to see whether there is an identifying mark nearby the selective ball-mounting pad. In case, no identifying mark is nearby the selective ball-mounting pad, the latter is a ball-mounting pad lacking the solder ball.

On the other hand, in case there is a ball-mounting pad without a solder ball and the nearby have an identifying mark formed thereon means that the ball is located at the selective ball-mounting pad section. Then, the remark on the production list or the model number is the only requirement to determine whether the missing solder ball is a normal or error.

Unlike to the conventional checking operation, the assembler or tester can check or compare the positions of the solder balls on the predetermined ball-mounting pads based on the production list in order to increase the testing rate magnificently and lowering the possibilities error judgment.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A circuit board comprising:
an upper surface;
a lower surface, said lower surface being formed with a plurality of bond pads including several ball-mounting pads and several selective ball-mounting pads; and
a plurality of identifying marks disposed on said lower surface for indicating said selective ball-mounting pads respectively.

2. The circuit board according to claim 1, wherein each of said identifying marks is in a triangular configuration, and has a vertex pointing toward a respective one of said selective ball-mounting pads.

3. The circuit board according to claim 1, wherein each of said identifying marks is a metal pad.

4. The circuit board according to claim 1, further comprising a solder mask that is disposed on said lower surface and that has a plurality of openings for exposing said identifying marks respectively.

5. A circuit board for receiving a die thereon, the circuit board comprising:
an upper surface;
a lower surface, said lower surface defining several ball-mounting regions and several selective ball-mounting regions; and
a plurality of identifying marks disposed on said lower surface in said selective ball-mounting regions for indicating said selective ball-mounting respectively.

6. The circuit board according to claim 5, wherein each of said identifying marks is in a triangular configuration, and has a vertex pointing toward a respective one of said selective ball-mounting regions.

7. The circuit board according to claim 5, wherein each of said identifying marks is a metal pad.

8. The circuit board according to claim 5, further comprising a solder mask that is disposed on said lower surface and that has a plurality of openings for exposing said identifying marks respectively.

9. A ball grid array package comprising:
a substrate having a lower surface formed with several ball-mounting regions, a selective ball-mounting region, and an identifying mark for indicating said selective ball-mounting region;
a die disposed on an upper surface of said substrate;
a molding resin for encapsulating said die on said substrate; and
a plurality of solder balls mounted on said lower surface of said substrate and coupled electrically to said die for establishing electrical communication with an external electronic device.

10. The ball grid array package according to claim 9, further comprising:
upper and lower circuit patterns respectively disposed on said upper and lower surfaces of said substrate; and
an internal wire extending through said substrate for interconnecting said upper and lower circuit patterns electrically.

11. The ball grid array package according to claim 9, further comprising a plurality wires electrically connecting said die and said upper surface of said substrate.

12. The ball grid array package according to claim 9, wherein said die is disposed on said upper surface of said substrate via flip-chip technique.

13. The ball grid array package according to claim 9, wherein said identifying mark is in a triangular configuration, and has a vertex for indicating said selective ball-mounting region;

14. The ball grid array package according to claim 9, wherein said identifying mark is a metal pad.

15. The ball grid array package according to claim 9, further comprising a solder mask that is disposed on said lower surface of said substrate and that has an opening for exposing said identifying mark.
